(19) United States
(12) Patent Application Publication
(10) Pub. No.: US 2025/0185263 A1
(43) Pub. Date: Jun. 5, 2025

(54) ROBUST ONO FILMS AND METHODS OF MAKING THEREOF

(71) Applicant: Texas Instruments Incorporated, Dallas, TX (US)

(72) Inventors: Saiful Islam, Lehi, UT (US); Gowrisankar Damarla, Lehi, UT (US); Manoj Jain, Plano, TX (US); Asad Haider, Plano, TX (US)

(21) Appl. No.: 18/524,608

(22) Filed: Nov. 30, 2023

(51) Int. Cl. C23C 16/02; C23C 16/04; C23C 16/06; C23C 16/34; C23C 16/40; C23C 16/50; C23C 16/56; H01L 21/02

(52) U.S. Cl. CPC H10D 1/68; C23C 16/02; C23C 16/045; C23C 16/06; C23C 16/345; C23C 16/402; C23C 16/50; C23C 16/56; H01L 21/02164; H01L 21/0217; H01L 21/0228; H01L 21/02312

(57) ABSTRACT

In one example, a method includes forming in a process chamber a first oxide film on a first metallic layer, forming in the process chamber a nitride film on the first oxide film, and forming in the process chamber a second oxide film on the nitride film. Forming the nitride film includes performing a process loop N number of times. The process loop includes depositing a nitride layer and performing an in-situ treatment of the nitride layer. N is a real number greater than one. The nitride film includes N nitride layers as a result of performing the process loop N number of times.

### BACKGROUND

Metal-Insulator-Metal (MIM) capacitors can be formed by using two metal films, with a thin insulating dielectric film disposed therebetween. Certain MIM capacitors may be considered two-dimensional (2D) in that the metal films overlap with one another along a single plane. Other MIM capacitors may be considered three-dimensional (3D) in that the metal films overlap with one another along multiple planes arranged at various angles to one another. The fabrication of MIM capacitors on the micro and nano scale presents certain difficulties, which can arise, for example, from differences in material properties between the metal film(s) and dielectric film(s) used.

### SUMMARY

In one example, a method includes forming in a process chamber a first oxide film on a first metallic layer, forming in the process chamber a nitride film on the first oxide film, and forming in the process chamber a second oxide film on the nitride film. Forming the nitride film includes performing a process loop N number of times. The process loop includes depositing a nitride layer and performing an in-situ treatment of the nitride layer. N is a real number greater than one. The nitride film includes N nitride layers as a result of performing the process loop N number of times.

In another example, a method includes stabilizing process conditions of a process chamber. An exposed surface of a substrate in the process chamber is pretreated with a mixture of gases introducing nitrogen and helium. A nitride film is formed on the substrate in the process chamber. Forming the nitride film includes performing a process loop N number of times. The process loop includes depositing a nitride layer and performing an in-situ treatment of the nitride layer. N is a real number greater than one. The nitride film includes N nitride layers as a result of performing the process loop N number of times. Residual gas is pumped out of the process chamber.

In another example, an apparatus includes a MIM capacitor. The MIM capacitor includes a first metallic layer, a first oxide film on the first metallic layer, a nitride film on the first oxide film, a second oxide film on the nitride film, and a second metallic layer on the second oxide layer. The nitride film has multiple nitride layers. Each nitride layer includes a densified portion at a surface facing away from the first oxide film.

### BRIEF DESCRIPTION OF THE DRAWINGS

FIG. 1A is cross-sectional view of a portion of an integrated circuit having an array of 3D metal-insulator-metal capacitors (MIMCAP).

FIG. 1B is an enlarged view of an example MIMCAP of FIG. 1A.

FIGS. 2A and 2B are representations of transmission electron microscope (“TEM”) images showing respective cross-sectional portions of an example MIMCAP fabricated in examples described herein.

FIG. 3 illustrates an example process flow that may be used to form part of the array of MIMCAPs of FIGS. 1A and 1B.

FIG. 4 is a graph showing a comparison of Fourier transform infrared spectroscopy (FTIR) data for in-situ treated films, as described herein, versus untreated films.

FIG. 5 is a graph comparing capacitance density versus breakdown voltage of MIMCAPs having in-situ treated films, as described herein, versus other MIMCAPs having untreated films.

FIG. 6 is a graph showing cumulative probability plots of breakdown voltages for MIMCAPs having untreated films.

FIG. 7 is a graph showing a cumulative probability plot of breakdown voltages for MIMCAPs having in-situ treated films, as described herein.

The same reference numbers or other reference designators are used in the drawings to designate the same or similar (functionally and/or structurally) features. The figures are not necessarily drawn to scale.

### DETAILED DESCRIPTION

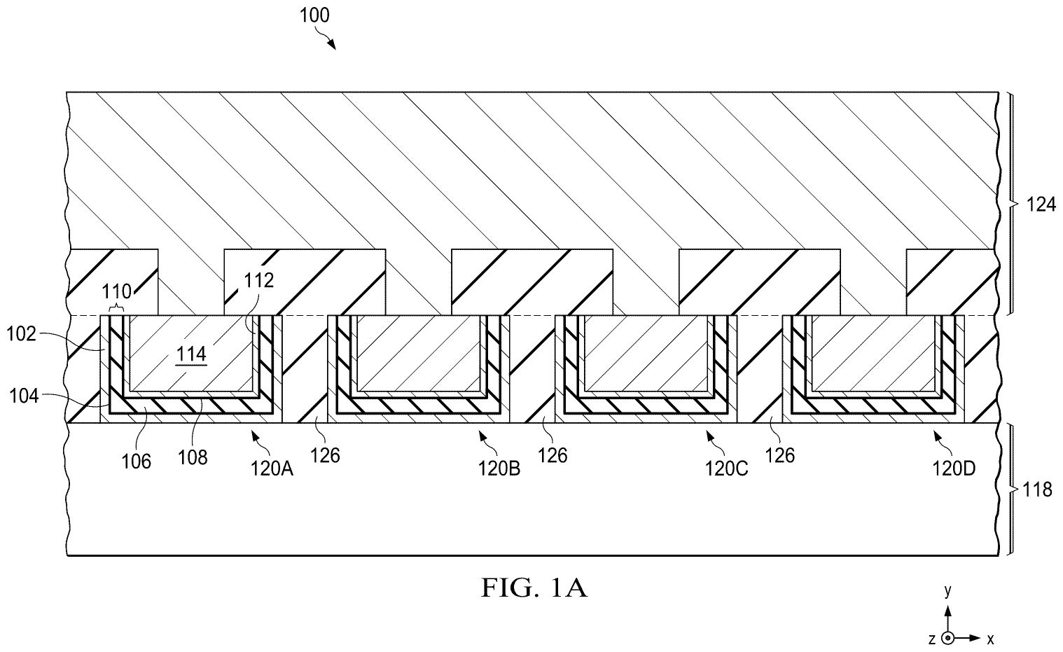

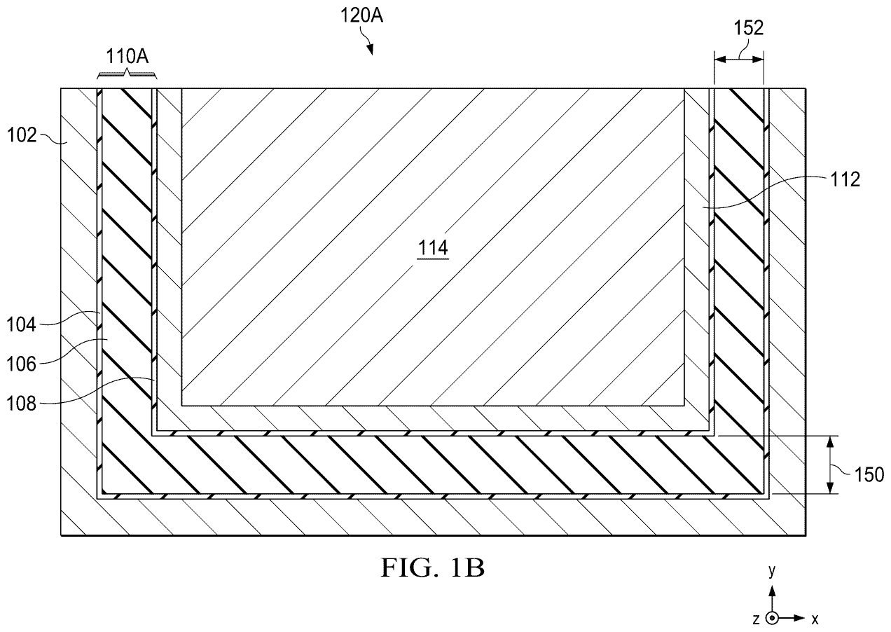

FIG. 1A is a cross-sectional view of a portion of an integrated circuit 100 having an array of 3D metal-insulator-metal capacitors (“MIMCAP”) 120 (also identified individually as 120A, 120B, 120C, and 120D). Each MIMCAP 120 has one or more of each of the following: first conductive layer 102, first oxide film 104, nitride film 106, second oxide film 108, second conductive layer 112, and conductive plug 114. First oxide film 104, nitride film 106, and second oxide film 108 are formed and treated, respectively as described in more detail herein, and may also be referred to as first treated oxide film 104 (or in-situ treated first oxide film), treated nitride film 106 (or in-situ treated nitride film), and second treated oxide film 108 (or in-situ treated second oxide film). First oxide film 104, nitride film 106, and second oxide film 108 are referred to herein collectively as oxide-nitride-oxide (“ONO”) film 110. The ONO film 110 is between the first and second conductive layers 102, 112 and the ONO film 110 is electrically insulative so as to electrically isolate the first and second conductive layers 102, 112 from one another.

Each MIMCAP 120 may have its first conductive layer 102 (e.g., Ta/TaN electrode metals) conductively coupled to a first metal layer 118 and may have its second conductive layer 112 (e.g., Ta/TaN electrode metals) and conductive plug 114 (e.g., tungsten) conductively coupled to second metal layer 124. The metal layers 118, 124 may be formed from copper, for example, or from any other suitable electrically conductive material.

In some examples, the ONO film 110 may be formed within a single process chamber. In this manner, overall process steps may be simplified to reduce fabrication cost while also enhancing reliability of the ONO film 110. Moreover, the temperature within the process chamber may be controlled to not exceed a threshold temperature. For example, the process chamber temperature used for forming the ONO film 110 may be maintained to not exceed 350° C. Constraining the processing temperature to an upper limit (e.g., 350° C., 375° C., 400° C., etc.) may avoid certain issues that could negatively impact quality and reliability, such as metal migration from first or second conductive layers 102, 112 into the ONO film 110, or such as complications arising from the different coefficients in thermal expansion between first conductive layer 102 and first oxide film 104 or second oxide film 108 and second conductive layer 112.

Using the example deposition process and in-situ treatments described herein, ONO film 110 may achieve high quality properties without necessarily requiring higher temperatures (e.g., greater than 550° C.). For example, ONO film 110 may include a nitride film (e.g., nitride film 106) having a step coverage that meets or exceeds 70%, even 80%. The step coverage is defined in more detail herein with reference to FIG. 1B. In addition, the ONO film 110 described herein may have enhanced densification and film quality, resulting in higher breakdown voltage, higher capacitance density, lower etch rate, for example.

TABLES 1 through 3 show wet etch rate data demonstrating film quality improvements that can be achieved using certain examples described herein. TABLE 1 below shows a comparison of wet etch data using diluted hydrofluoric acid (DHF) 100:1 to etch through oxide films and nitride films with and without the in-situ treatments described herein.

TABLE 1

| | Untreated | Treated | Untreated | Treated |
|---|---|---|---|---|
| DHF 100:1 | Oxide | Oxide | Nitride | Nitride |
| Etch rate | ~140 | ~80 | ~160 | ~60 |
| (Å/minute) | | | | |

As shown in TABLE 1, above, the wet etch rate is approximately 40% lower in treated oxides film relative to untreated oxide film. In addition, the wet etch rate of treated nitride film 106 is approximately 250% lower than untreated nitride film. Lower etch rates, such as those shown in TABLE 1, can be indicative of better molecular bonding of the material being etched.

TABLE 2 below shows wet etch data obtained using a three-step etch of the bulk film and compares the results achieved from an untreated oxide film versus oxide film treated according to example processing described herein (e.g., first and second treated oxide films 104, 108).

TABLE 2

| Wet Etch Test | Untread | Treated |
|---|---|---|
| (Å/minute) | Oxide | Oxide |
| Wet Etch Rate-1 | 125 | 75 |
| Wet Etch Rate -2 | 144 | 80 |
| Wet Etch Rate-3 | 161 | 82 |

TABLE 3 below shows wet etch data obtained using a three-step etch of the bulk film and compares the results achieved from an untreated nitride film versus a nitride film treated according to example processing described herein (e.g., treated nitride film 106).

TABLE 3

| Wet Etch Test | Untreated | Treated |
|---|---|---|
| (Å/minute) | Nitride | Nitride |
| Wet Etch Rate-1 | 148.5 | 52 |
| Wet Etch Rate-2 | 165 | 58.5 |
| Wet Etch Rate-3 | 182.5 | 62.5 |

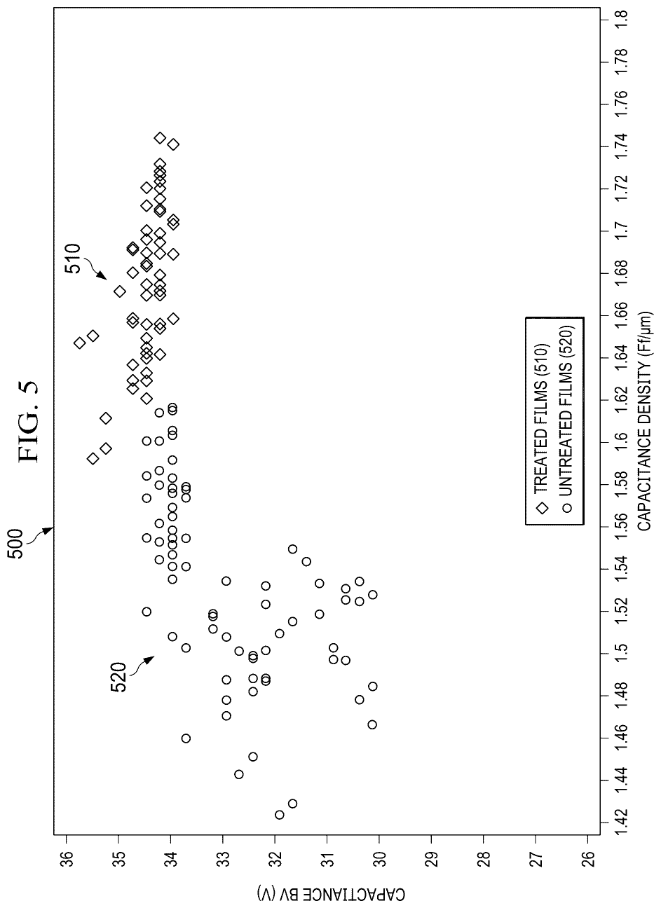

As shown in TABLES 2 and 3, above, treated oxide film and treated nitride film both show marked improvement in terms of a consistent wet etch rate across the depth of the film. A more consistent etch rate, such as that represented by the data shown in TABLES 2 and 3 for treated oxide and nitride films, can be indicative of better molecular bonding of the material being etched throughout the films. The electrical data shown in FIGS. 5 through 7, and described further below, further demonstrates improvements in film quality that can be achieved by certain example processing described herein.

Overall process flow used to form MIMCAPs 120 includes selectively removing portions of a substrate (e.g., a dielectric layer 126 over the first metal layer 118 through a wet or dry etch) with sufficient depth to expose an upper surface of the first metal layer 118 at a base of each trench where the MIMCAPs 120 are to be formed. The selective removal can be configured to form an array of trenches (not explicitly shown), with each trench defining a cavity (e.g., void, orifice, opening) that can be filled with various materials (e.g., materials of first conductive layer 102, first oxide film 104, nitride film 106, second oxide film 108, second conductive layer 112, conductive plug 114) used to form a respective MIMCAPs 120.

First conductive layer 102 may be formed within each trench, such that first conductive layer 102 covers the sidewalls and base of each trench. First conductive layer 102 may be formed, for example, by depositing one or more layers of electrically conductive material (e.g., tantalum or tantalum-nitride).

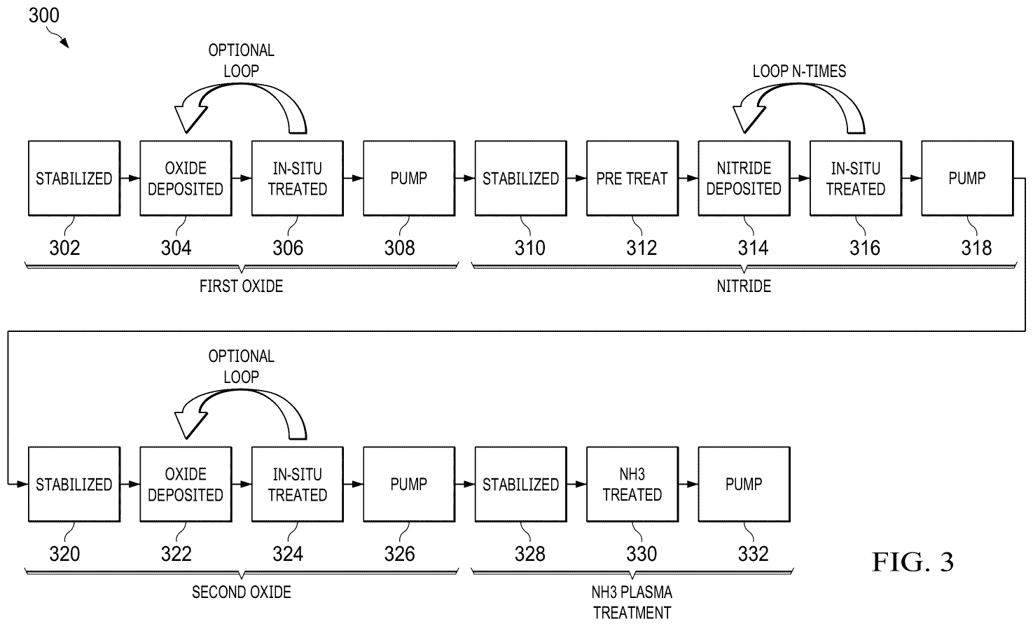

First oxide film 104 may be formed on first conductive layer 102, such that first oxide film 104 covers the sidewalls and base of first conductive layer 102. Example processing that may be used to form first oxide film 104 is described further herein with reference to steps 302 through 308 of FIG. 3. First oxide film 104 may be described as “treated” because its formation includes depositing an oxide layer and then treating the deposited oxide layer (e.g., exposing the oxide layer to a mixture of gases), as described further herein with reference to steps 304 through 306 of FIG. 3. Once formed, first oxide film 104 includes a sidewall portion formed on sidewalls of the first conductive layer 102 and a base portion formed on a base of the first conductive layer 102. The sidewall portion of the first oxide film 104 has a side thickness (e.g., measured in a direction parallel to the x-axis shown) and the base portion of the first oxide film 104 has a base thickness (e.g., measured in a direction parallel to the y-axis shown). In some examples, the base thickness of the base portion of first oxide film 104 may be 60 Å.

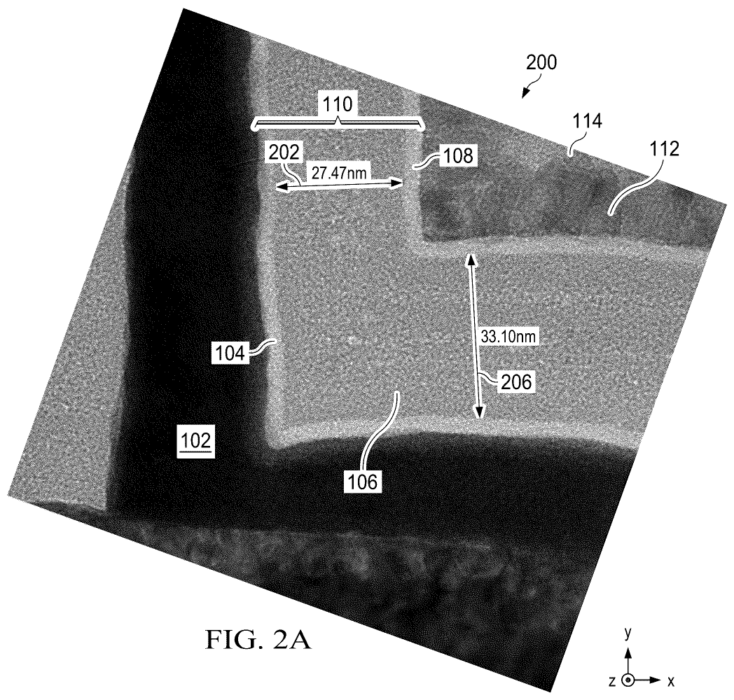

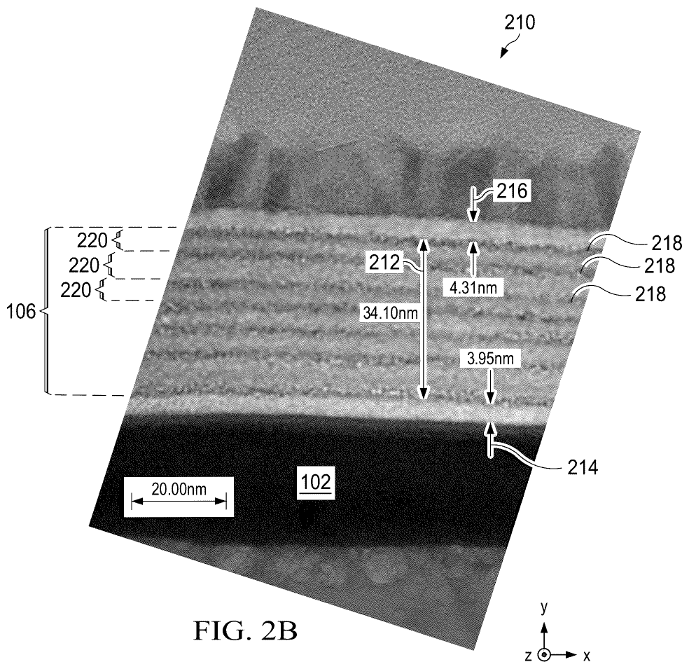

Nitride film 106 may be formed on the first oxide film 104. The nitride film 106 represents a plurality of nitride layers formed in succession, the first nitride layer being formed on first oxide film 104, such that nitride film 106 covers the first oxide film 104. Example processing that may be used to form treated nitride film 106 is described further herein with reference to steps 310 through 318 of FIG. 3. Once formed, nitride film 106 includes a sidewall portion formed on the sidewall portion of the first oxide film 104 and a base portion formed on the base portion of the first oxide film 104. The sidewall portion of the nitride film 106 has a side thickness (e.g., measured in a direction parallel to the x-axis shown) and the base portion of the nitride film 106 has a base thickness (e.g., measured in a direction parallel to the y-axis shown). In some examples, the base thickness of nitride film 106 may be 500 Å, where nitride film 106 includes a stack of multiple nitride layers that are sequentially deposited and in-situ treated using the process loop described further herein with reference to FIGS. 2A through 3.

Second oxide film 108 may be formed on nitride film 106, such that second oxide film 108 covers the nitride film 106. Example processing that may be used to form second oxide film 108 is described further herein with reference to steps 320 through 326 of FIG. 3. Second oxide film 108 may be described as “treated” because its formation includes depositing an oxide layer and then treating the deposited oxide layer, as described further herein with reference to steps 322 through 324 of FIG. 3. Second oxide film 108 may further be treated in a manner that prepares the outer surface thereof for the subsequent formation of second conductive layer 112. Example processing that may be used to treat the outer surface of second treated oxide film 108 is described further herein with reference to steps 328 through 332 of FIG. 3. Once formed, second oxide film 108 includes a sidewall portion formed on the sidewall portion of the nitride film 106 and a base portion formed on the base portion of the nitride film 106. The sidewall portion of the second oxide film 108 has a side thickness (e.g., measured in a direction parallel to the x-axis shown) and the base portion of the second oxide film 108 has a base thickness (e.g., measured in a direction parallel to the y-axis shown). In some examples, the base thickness of the base portion of the second oxide film 108 may be 60 Å.

Second conductive layer 112 may be formed on second oxide film 108, such that second conductive layer 112 covers the second oxide film 108. The second conductive layer 112 may be formed, for example, by depositing one or more layers of electrically conductive material (e.g., tantalum or tantalum-nitride).

Conductive plug 114 is formed on the second conductive layer 112. Conductive plug 114 may be formed, for example, by depositing one or more layers of electrically conductive material, such as tungsten. The conductive plug 114 may be deposited with sufficient thickness to at least fill the remainder volume of the trenches corresponding to each MIMCAPs 120. Additional processing steps may be subsequently performed to form the second metal layer 124. In this example, metal layer 124 contacts respective upper surfaces of MIMCAPs 120 (e.g., the conductive plugs 114).

FIG. 1B is an enlarged view of the MIMCAP 120A of FIG. 1A. Dimension 152 represents a side thickness (e.g., end-to-end side thickness of a sidewall portion) of nitride film 106 along a cross-sectional plane parallel to the x-axis shown—e.g., measured in a direction parallel to the x-axis. Dimension 150 represents a base thickness (e.g., end-to-end base thickness of a base portion) of nitride film 106 along a cross-sectional plane parallel to the y-axis shown—e.g., measured in a direction parallel to the y-axis. In this context, a step coverage of nitride film 106 may be defined as a ratio of the side thickness 152 relative to the base thickness 150 of nitride film 106—i.e., the side thickness 152 divided by the base thickness 150. In some examples, dimension 150 may be greater than dimension 152 such that the step coverage is less than one. In some examples, due to the manner in which nitride film 106 is formed (e.g., through multiple depositions of nitride layers, each nitride layer being formed by flux of materials primarily traveling in the negative y direction), the nitride layer on a horizontal surface may form thicker than on a nearly vertical surface, such that the step coverage may be less than one. In some examples, nitride film 106 may have a step coverage of at least 70%. In some examples, nitride film 106 may have a step coverage of at least 80%. In some examples, nitride film 106 may have a step coverage within a range of approximately 70% to approximately 85%, inclusively.

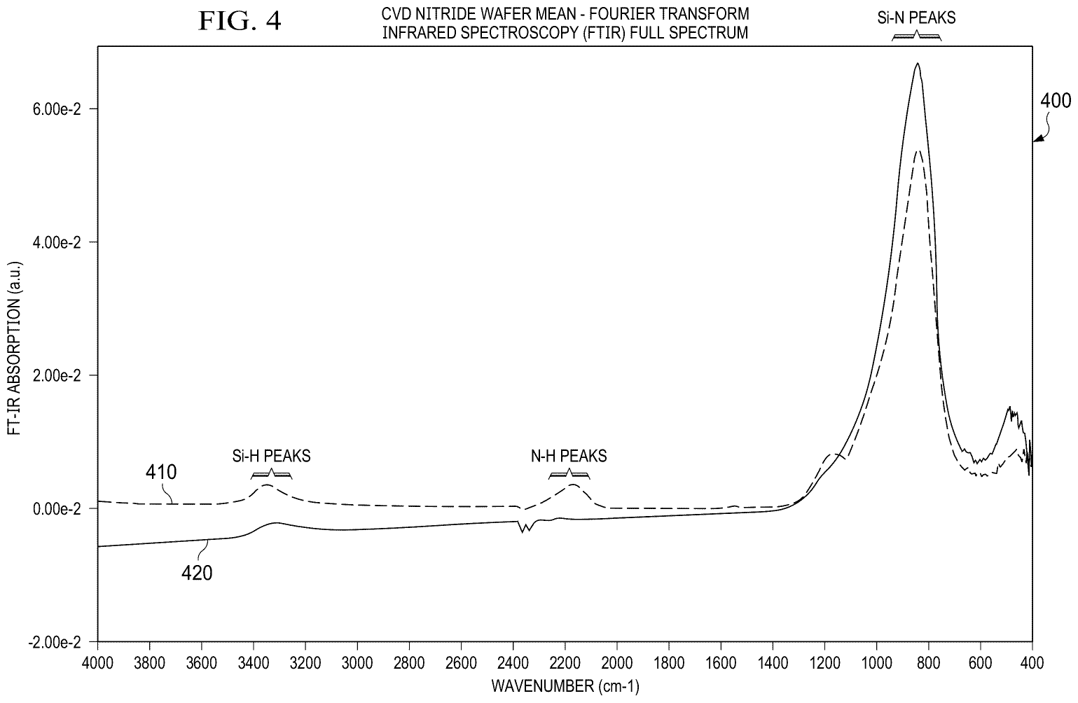

As described further herein with reference to FIGS. 2A through 7, a process loop (e.g., including steps 314 and 316 of FIG. 3) may be performed that results in nitride film 106 having increased densification and enhanced step coverage. Enhancing the step coverage of nitride film 106 and increasing its densification may increase the breakdown voltage and capacitance density (and/or may decrease etch rates) such that devices including the nitride film 106 (e.g., MIMCAP 120A) may have improved performance and reliability, as described further herein with reference to TABLES 1 through 3 and FIGS. 4 through 7.

FIGS. 2A and 2B are representations of transmission electron microscope (“TEM”) images 200, 210 showing respective cross-sectional portions of an example MIMCAP structure with ONO film 110 fabricated based on example processes described herein. TEM image 200 of FIG. 2A may be a representation of the bottom-left corner of MIMCAP 120A, as shown in FIGS. 1A and 1B, in which ONO film 110 is formed on the first conductive layer 102. As described herein with reference to FIGS. 1A and 1B, the ONO film 110 shown in FIG. 2A includes a first oxide film 104, a nitride film 106, and a second oxide film 108.

TEM image 200 of FIG. 2A shows an example measurement 202 of the sidewall thickness (e.g., side thickness 152) of nitride film 106 measured parallel to the x-axis. In this example, measurement 202 is 27.47 nm. TEM image 200 further shows an example measurement 206 of the base thickness (e.g., base thickness 150) of nitride film 106 measured parallel to the y-axis. In this example, measurement 206 is 33.10 nm. Of these example measurements 202, 206, the ratio of the sidewall thickness (27.47 nm) of nitride film 106 relative to the base thickness (33.10 nm) of nitride film 106, hence the step coverage is approximately 83%.

TEM image 210 of FIG. 2B shows example thickness measurements 212, 214, 216 parallel to the y-axis. TEM image 210 may be a representation of a middle portion of MIMCAP 120A, as shown in FIGS. 1A and 1B, in which ONO film 110 is formed on the first conductive layer 102. In this example, measurement 212 indicates 34.10 nm as the base thickness of nitride film 106, measurement 214 indicates 3.95 nm as the base thickness of the first oxide film 104, and measurement 216 indicates 4.31 nm as the base thickness of the second oxide film 108.

TEM image 210 further shows details of the nitride film 106. For example, the nitride film 106 includes multiple nitride layers 220. Each of the nitride layers 220 has grain lines 218 (or portions 218 of nitride layer 220 with relatively dark contrast) extending along the base of the nitride film 106 in a direction substantially parallel to the x-axis and substantially perpendicular to the direction of successive deposition. These grain lines 218 are formed as the result of performing a process loop N number of times, in which each iteration of the process loops (or process cycles) includes depositing a nitride layer and performing an in-situ treatment of the deposited nitride layer, as described herein with reference to steps 314 through 316 of FIG. 3. The in-situ treatment is devised to densify each nitride layer 220, and the surface (or a portion proximate the surface) of the nitride layer 220 is expected to be densified relatively more than the rest of the nitride layer 220. As such, the grain lines 218 may also be referred to as densified portions 218. The number of distinguishable grain lines 218 within nitride film 106 may correspond with the number of times (N) the process loop is sequentially performed.

TEM image 210 is representative of an example nitride film 106 formed by performing the process loop at least seven times (i.e., N=7), such that there are at least seven distinguishable nitride layers 220 shown in nitride film 106. In this example, each nitride layer 220 of nitride film 106 has a respective thickness along the y-axis substantially similar to respective thicknesses of the first and second oxide films 104, 108 shown (e.g., at measurements 214, 216, respectively). Although the ONO film 110 of TEM image 200 of FIG. 2A is expected to have multiple densified portions 218 similar to the ONO film 110 of TEM image 210, the TEM image 200 does not show sufficient contrast to delineate such densified portions 218—e.g., due to thickness variations of TEM specimen or due to directions of incident electron beams during TEM analyses.

FIG. 3 is a flowchart 300 illustrating an example process flow that may be implemented to form the ONO film 110 of MIMCAPs 120. The example process flow includes steps 302 through 332. In some examples, the entire process flow from steps 302 through 332 is performed within a single process chamber without breaking vacuum—e.g., while maintaining a pressure of the process chamber at a subatmospheric level throughout the steps 302 through 332. In some examples, the entire process flow from steps 302 through 332 is performed at a temperature less than or equal to 350 degrees Celsius. Each MIMCAP (e.g., 120A, 120B, 120C, 120D), once formed, has an ONO film 110 between a first conductive layer 102 and a second conductive layer 112. As described herein with reference to FIGS. 1A through 2B, the ONO film 110 includes nitride film 106 disposed between first and second oxide films 104, 108, in which the nitride film 106 has multiple nitride layers.

Example processing that can be used to form first oxide film 104 is described with reference to steps 302 through 308. Prior to beginning the process flow, a substrate (e.g., a semiconductor wafer) including the first conductive layer 102 deposited in trenches is placed on a wafer chuck (e.g., a pedestal configured to hold the substrate) of the process chamber such that base portions of the trenches are substantially parallel to the wafer chuck. The process chamber is stabilized with process conditions, such as, for example, gas flow, gas temperature, and gas pressure (step 302). Stabilizing the process chamber may result in stabilizing all the gas flows, pressure, temperature, heater spacing, etc., before executing subsequent process steps. Such stabilization may improve the consistency of layer(s) being performed.

An oxide layer (e.g., containing SiO₂) is deposited to form the first oxide film 104 (step 304). The deposition may include, for example, a plasma enhanced chemical vapor deposition (PECVD) or plasma enhanced atomic layer deposition (PEALD). In some examples, one or more inert gases (e.g., He, Ar, etc.) are used during the deposition. Using the inert gas during the deposition may facilitate generating the oxide layer that is more densified when compared to the same process without using the inert gas. The deposition may be performed using a mixture of SiH₄, N₂O, and He at 350° C., for example, which may produce the oxide layers of the first oxide film 104 having high quality and high conformality (e.g., step coverage with the range of 80% to 90% or greater).

The deposited oxide layer is in-situ treated (step 306). For example, the deposited oxide layer may be exposed to a plasma containing a plurality of gases. The plurality of gases may include, for example, nitrogen, N₂O, argon, helium, or a combination thereof. The dilution of certain reactive gasses (e.g., N₂O) with one or more inert gases (e.g., Ar, He) during the in-situ treatment may have certain advantageous effects: (1) reducing concentration of Si—H bonding groups in the deposited oxide layer (i.e., removing the hydrogen content from the oxide layer); (2) driving the deposited oxide layer toward SiO₂ stoichiometric composition; and (3) densifying the deposited oxide layer (e.g., as shown in the wet etch rate of TABLES 1 and 2). In other words, treating a limited thickness of deposited oxide layer at a time helps reduce silicon-hydrogen bonds by removing hydrogen bonded with silicon and replacing those dangling silicon bonds with more oxygen, which can increase film quality and purity.

Steps 304 and 306 may be included within a process loop performed N number of times, where N is a real number greater than or equal to one. Each iteration of the process loop can include depositing an oxide layer (step 304) and performing an in-situ treatment of the deposited oxide layer (step 306), such that the first oxide film 104 includes a stack of at least N oxide layers (or N treated oxide layers). In some examples, the base thickness along the base of the deposited first oxide film 104 (including one or more deposited oxide layers) may range between approximately 30 Å and approximately 80 Å—e.g., approximately 40 Å as described with reference to FIGS. 2A and 2B, approximately 60 Å as described with reference to FIGS. 1A and 1B. For example, the first oxide film 104 can have a cumulative thickness of approximately 60 Å after performing the aforementioned process loop 3 times (i.e., N=3), in which each iteration of the process loop involves depositing an oxide layer with a thickness of approximately 20 Å, followed by an in-situ treatment of the deposited oxide layer.

Residual gas is pumped out of the process chamber (step 308).

Example processing that can be used to form a plurality of nitride layers (e.g., in-situ treated nitride layers) of the nitride film 106 is described with reference to steps 310 through 318. The process chamber is stabilized with process conditions, such as, for example, gas flow, gas temperature, and gas pressure (step 310). Stabilizing the process chamber may result in stabilizing all the gas flows, pressure, temperature, heater spacing, etc., before executing subsequent process steps. Such stabilization may improve the consistency of layer(s) being performed.

A pre-treatment process is performed in the process chamber (step 312). The pre-treatment process may be used to pretreat the exposed surface of the first oxide film 104 with nitrogen or with a combination of nitrogen and an inert gas (e.g., helium). Such treatment may result in removing volatile materials or moisture from the first oxide film 104 so as to enhance adhesion property of the first oxide film 104 with respect to the nitride layer (e.g., the nitride layer 220 described with reference to FIG. 2B) that will be subsequently deposited on the first oxide film 104 (in step 314). Such pre-treatment may also result in improving the interface between the first oxide film 104 and a nitride layer (e.g., the nitride layer 220) subsequently deposited thereon (in step 314). In some examples, the pre-treatment process (step 312) includes introducing nitrogen gas (or a mixture of nitrogen and helium) in the process chamber, thereby resulting in the exposed surface of the first oxide film 104 at least partially bonded with nitrogen (or at least partially bonded with nitrogen and helium).

A deposition process is performed in the process chamber, in which a nitride layer (e.g., containing SiN) is deposited (step 314). The deposition may include, for example, PECVD or PEALD. In some examples, one or more inert gases (e.g., He, Ar) are used during the deposition. The deposition may be performed using a mixture of SiH₄, NH₃, Ar, He, and N₂ at 350° C., for example, which may produce an example nitride film 106 having high quality and high conformality—e.g., with a step coverage described with reference to FIG. 1B, which may be at least 83%, for example, as determined based on the TEM image 200 of FIG. 2A.

An in-situ treatment of the deposited nitride layer is performed in the process chamber (step 316). The in-situ treatment includes exposing the last deposited nitride layer to a plasma containing a plurality of gases. The plurality of plasma gases may include, for example, nitrogen, argon, helium, or a combination thereof. In some examples, the in-situ treatment process may last for approximately 25 seconds. The dilution of plasma gas with one or more inert gases (e.g., Ar, He, or both) during the in-situ treatment may have the following advantageous effects: (1) reducing concentration of Si—H and N—H bonding groups in the deposited nitride layer (i.e., removing the hydrogen content from the deposited nitride layer); (2) driving the deposited films toward Si₃N₄ stoichiometric composition; and (3) densifying the deposited nitride layer (e.g., as shown in the wet etch rate of TABLES 1 and 3). In other words, treating a limited amount of nitride layer at a time reduces silicon-hydrogen bonds and nitrogen-hydrogen bonds by removing hydrogen from deposited nitride layer so as to increase silicon bonded with nitrogen as described in more detail with reference to FIG. 4. In this manner, the nitride film 106 can have increased film quality and purity. In some examples, the process chamber includes a gas line dedicated for supplying argon. In some examples, the process chamber includes a first gas line dedicated for supplying argon and a second gas line dedicated for supplying helium.

Steps 314 and 316 may be included within a process loop performed N number of times, where N is a real number greater than one. Each iteration of the process loop can include depositing a nitride layer (step 314) and performing an in-situ treatment of the deposited nitride layer (step 316), such that, upon completion of the process loop, the resultant nitride film 106 will include at least N nitride layers. As described with reference to FIGS. 1A and 1B, for example, nitride film 106 can have a cumulative thickness of approximately 500 Å after performing the aforementioned process loop 10 times (i.e., N=10), in which each iteration of the process loop involves depositing a nitride layer with a thickness of approximately 50 Å, followed by an in-situ treatment of the deposited nitride layer. As another example, nitride film 106 can have a cumulative thickness of approximately 500 Å after performing the aforementioned process loop 5 times (i.e., N=5), in which each iteration of the process loop involves depositing a nitride layer with a thickness of approximately 100 Å, followed by an in-situ treatment of the deposited nitride layer. As another example, nitride film 106 can have a cumulative thickness of approximately 600 Å after performing the aforementioned process loop 6 times (i.e., N=6), in which each iteration of the process loop involves depositing a nitride layer with a thickness of approximately 100 Å, followed by an in-situ treatment of the deposited nitride layer.

Although foregoing examples describe nitride film 106 including multiple nitride layers that each has approximately the same thickness, the present disclosure is not limited thereto. For example, nitride film 106 can have a cumulative thickness of approximately 500 Å after performing the aforementioned process loop 7 times (i.e., N=7), in which two or more iterations of the process loop involve depositing a nitride layer with a varying thickness (e.g., thicknesses of 50 Å, 75 Å, 75 Å, 100 Å, 75 Å, 75 Å, and 50 Å corresponding to N=1 through 7 iterations) followed by an in-situ treatment of each of the deposited nitride layer. Other thickness variations of nitride layers for forming nitride film 106 are within the scope of the present disclosure.

Residual gas is pumped out of the process chamber (step 318).

As with the processing steps described with reference to forming the first oxide film 104, example processing that can be used to form second oxide film 108 is described with reference to steps 320 through 326. In some examples, steps 320 through 326 may be substantially similar to those described previously with reference to steps 302 through 308.

The process chamber is stabilized with process conditions, such as, for example, gas flow, gas temperature, and gas pressure (step 320). Stabling the process chamber may result in stabilizing all the gas flows, pressure, temperature, heater spacing, etc., before executing subsequent process steps. Such stabilization may improve the consistency of layer(s) being performed.

An oxide layer (e.g., containing SiO₂) is deposited to form the second oxide film 108 (step 322). The deposition may include, for example, PECVD or PEALD. In some examples, one or more inert gases (e.g., He, Ar, etc.) are used during the deposition. Using the inert gas during the deposition may facilitate generating the oxide layer that is more densified when compared to the same process without using the inert gas. The deposition may be performed using a mixture of SiH₄, N₂O, and He at 350° C., for example, which may produce the oxide layers of the first oxide film 104 having high quality and high conformality (e.g., step coverage with the range of 80% to 90% or greater).

The deposited oxide layer is in-situ treated (step 324). For example, the deposited oxide layer may be exposed to a plasma containing a plurality of gases. The plurality of gases may include, for example, nitrogen, N₂O, argon, helium, or a combination thereof. The dilution of certain reactive gasses (e.g., N₂O) with one or more inert gases (e.g., Ar, He) during the in-situ treatment may have certain advantageous effects: (1) reducing concentration of Si—H bonding groups in the deposited oxide layer (i.e., removing the hydrogen content from the oxide layer); (2) driving the deposited oxide layer toward SiO₂ stoichiometric composition; and (3) densifying the deposited oxide layer (e.g., as shown in the wet etch rate of TABLES 1 and 2). In other words, treating a limited thickness of deposited oxide layer at a time helps reduce silicon-hydrogen bonds by removing hydrogen bonded with silicon and replacing those dangling silicon bonds with more oxygen, which can increase film quality and purity.

Steps 322 and 324 may be included within a process loop performed N number of times, where N is a real number greater than or equal to one. Each iteration of the process loop can include depositing an oxide layer (step 322) and performing an in-situ treatment of the deposited oxide layer (step 324), such that the second oxide film 108 includes a stack of at least N oxide layers (or N treated oxide layers). In some examples, the base thickness along the base of the deposited second oxide film 108 (including one or more deposited oxide layers) may range between approximately 30 Å and approximately 80 Å—e.g., approximately 40 Å as described with reference to FIGS. 2A and 2B, approximately 60 Å as described with reference to FIGS. 1A and 1B. For example, the second oxide film 108 can have a cumulative thickness of approximately 60 Å after performing the aforementioned process loop 3 times (i.e., N=3), in which each iteration of the process loop involves depositing an oxide layer with a thickness of approximately 20 Å, followed by an in-situ treatment of the deposited oxide layer.

Residual gas is pumped out of the process chamber (step 326).

Example processing that can be used to treat the deposited first oxide film, nitride, film, and second oxide film is described with reference to steps 328 through 332.

The process chamber is stabilized with process conditions, such as, for example, gas flow, gas temperature, and gas pressure (step 328). Stabilizing the process chamber may result in stabilizing all the gas flows, pressure, temperature, heater spacing, etc., before executing subsequent process steps. Such stabilization may improve the consistency of layer(s) being performed.

The deposited first oxide film, nitride, film, and second oxide film are treated in the process chamber with ammonia (NH₃) gas (step 330).

Residual gas is pumped out of the process chamber (step 332).

As described with reference to steps 302 through 332, the same process chamber can be used to form ONO film 110 in its entirety, including first oxide film 104, nitride film 106, and second oxide film 108. In addition, in some examples, the example process flow of flowchart 300 can achieve a high quality ONO film 110 while satisfying the processing constraint that the temperature within the process chamber does not exceed a threshold temperature (e.g., 350° C.).

FIG. 4 is a graph 400 showing Fourier transform infrared spectroscopy (FTIR) data for an untreated nitride film (410) versus a treated nitride film (420), in which the x-axis plots wavenumber (in cm⁻¹ units) and the y-axis plots FT-IR absorption (a.u.). As shown in FIG. 4, the Si—H peaks (at approximately 3340 cm-1) are reduced by the in-situ treatment of the nitride film at 350° C. (420) relative to the untreated nitride film (410). Similarly, the N—H peaks (at approximately 2160 cm-1) are reduced by the in-situ treatment of the nitride film at 350° C. (420) relative to the untreated nitride film (410). Finally, the Si—N peaks (at approximately 840 cm-1) are enhanced (e.g., increased) by the in-situ treatment of the nitride film at 350° C. (420) relative to the untreated nitride film (410). The data shown in graph 400 indicates that the nitride film has more Si—N bonding and less Si—H bonding (and less N—H bonding) than the untreated nitride film. This comparative difference further indicates that a higher quality nitride film, lower etch rate, and better electrical performance can be achieved by the various example in-situ treatment processes described herein.

FIG. 5 is a graph 500 plotting certain measured electrical performance data of MIMCAPs with (510) and without (520) the in-situ treatment of the first oxide film 104, nitride film 106, and second oxide film 108 of the ONO film 110 described herein. The x-axis plots capacitance density (in units of fF/μm²) and the y-axis plots breakdown voltage (in volts). It some examples, it is desirable for the capacitance breakdown voltage and capacitance density to both be as high as possible. As FIG. 5 shows, the collection of points corresponding to the ONO films 510 generally has both a higher capacitance density and higher breakdown voltage than the collection of points corresponding to untreated ONO films 520. A comparison of respective medians of the collection of data points shows the treated ONO films 510 generally have approximately 8% higher capacitance density than untreated ONO films 520. In addition, the breakdown voltage data corresponding to the treated ONO films 510 has significantly reduced variance relative to the breakdown voltage date corresponding to the untreated ONO films 520. The relative increase in higher capacitance density and higher breakdown voltage may contribute to a significant improvement in device performance.

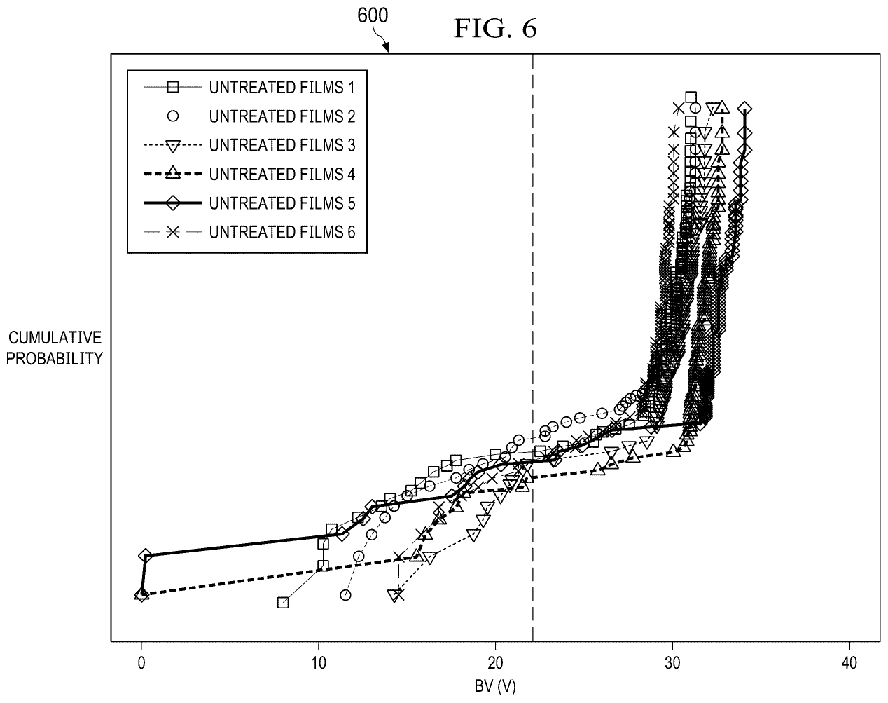

FIG. 6 is a graph 600 showing cumulative probability plots of breakdown voltages (in volts) for various MIMCAPs having various untreated ONO films. As can be seen by graph 600, use of untreated ONO film can result in a tail where the breakdown voltage drops off rapidly.

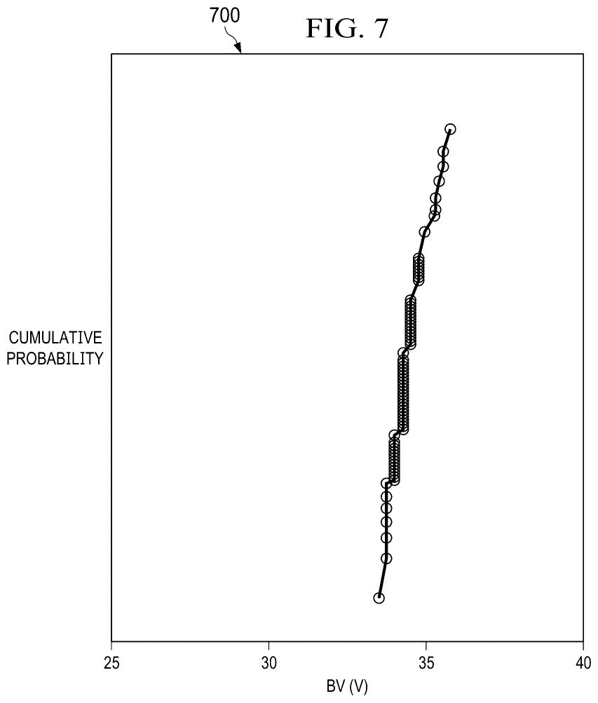

FIG. 7 is a graph 700 showing a cumulative probability plot of breakdown voltages for various MIMCAPs (e.g., MIMCAPs 120A, 120B, 120C, 120D) having treated ONO films, as described herein. As can be seen by graph 700, forming the constituent films 104, 106, and 108 of ONO film 110 based on the processing steps described herein can result in eliminating the tail shown in graph 600, hence reducing the variance in breakdown voltage, and increasing the median breakdown voltage (e.g., by more than four volts to approximately 35 volts or higher), all of which may contribute to a significant improvement in the performance and operational lifetime of MIMCAPs 120.

Although above-described examples are based on a 3D MIMCAP including a base portion and a sidewall portion, the present disclosure is not limited thereto. For example, the process loops or process cycles (e.g., the example process flow of the flowchart 300 or any portion thereof) can be used to generate a 2D MIMCAP. Moreover, although certain examples are described herein in the context of fabricating an integrated circuit 100 have MIMCAPs, certain processing (e.g., the disclosed process flow of the flowchart 300 or any portion thereof) may be used in fabricating other features of an integrated circuit. For example, the process steps described herein may be used in fabricating features coupled to a transistor (e.g., of an embedded flash device).

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. To aid the Patent Office, and any readers of any patent issued on this application, in interpreting the claims appended hereto, applicant notes that there is no intention that any of the appended claims invoke 35 U.S.C. § 112(f) as it exists on the date of filing hereof unless the words “means for” or “step for” are explicitly used in the claim language.

In the foregoing descriptions, for purposes of explanation, numerous specific details are set forth to provide a thorough understanding of one or more examples. However, this disclosure may be practiced without some or all these specific details, as will be evident to one having ordinary skill in the art. In other instances, well-known process steps or structures have not been described in detail in order not to unnecessarily obscure this disclosure. In addition, while the disclosure is described in conjunction with examples, this description is not intended to limit the disclosure to the described examples. To the contrary, the description is intended to cover alternatives, modifications, and equivalents as may be included within the spirit and scope of the disclosure as defined by the appended claims.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples may be included in an integrated circuit and other elements may be external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A method comprising:
forming in a process chamber a first oxide film on a first metallic layer;
forming in the process chamber a nitride film on the first oxide film, wherein forming the nitride film includes performing a process loop N number of times, the process loop including depositing a nitride layer and performing an in-situ treatment of the nitride layer, N being a real number greater than one, the nitride film including N nitride layers as a result of performing the process loop N number of times; and
forming in the process chamber a second oxide film on the nitride film.

2. The method of claim 1, further comprising:
treating in the process chamber the first oxide film, the nitride film, and the second oxide film with ammonia (NH₃) gas.

3. The method of claim 1, wherein forming the first oxide film, forming the nitride film, and forming the second oxide film are performed while maintaining a pressure of the process chamber at a subatmospheric level.

4. The method of claim 1, wherein forming the first oxide film, forming the nitride film, and forming the second oxide film are performed at a temperature less than or equal to 350 degrees Celsius.

5. The method of claim 1, further comprising:
forming a second metallic layer on the second oxide film.

6. The method of claim 5, wherein the first metallic layer and the second metallic layer separated by the first oxide film, the nitride film, and the second oxide film form a metal-insulator-metal capacitor.

7. The method of claim 1, further comprising:
exposing, prior to forming the nitride film, the first oxide film to a mixture of gases including nitrogen and one or more of argon and helium.

8. The method of claim 1, wherein the in-situ treatment includes exposing the nitride layer to a mixture of gases including nitrogen and one or more of argon and helium.

9. The method of claim 1, wherein each one of the N nitride layers includes a densified portion at a surface of the nitride layer as a result of performing the in-situ treatment.

10. The method of claim 1, wherein forming the nitride film further includes:
performing a pre-treatment process prior to performing the process loop, the pre-treatment process including exposing a surface of the first oxide film with nitrogen gas.

11. The method of claim 1, wherein forming the first oxide film includes one or more process cycles, each process cycle having:
depositing a first oxide layer; and
exposing the first oxide layer to a mixture of gases with nitrogen and one or more of argon and helium.

12. The method of claim 11, wherein depositing the first oxide layer includes supplying helium to the process chamber.

13. The method of claim 11, wherein forming the second oxide film includes one or more process cycles, each process cycle having:
depositing a second oxide layer; and
exposing the second oxide layer to a mixture of gases with nitrogen and one or more of argon and helium.

14. The method of claim 13, wherein depositing the first oxide layer includes supplying helium to the process chamber.

15. The method of claim 1, wherein the nitride film has a step coverage of at least 70%, in which the step coverage is defined as a first thickness of the nitride film on a first surface substantially perpendicular to a wafer chuck of the process chamber divided by a second thickness of the nitride film on a second surface substantially parallel to the wafer chuck.

16. The method of claim 1, wherein the process chamber includes a gas line dedicated for supplying argon.

17. A method comprising:
stabilizing process conditions of a process chamber;
pretreating an exposed surface of a substrate in the process chamber with a mixture of gases including nitrogen and helium;
forming a nitride film on the substrate in the process chamber, wherein forming the nitride film includes performing a process loop N number of times, the process loop including depositing a nitride layer and performing an in-situ treatment of the nitride layer, N being a real number greater than one, the nitride film including N nitride layers as a result of performing the process loop N number of times; and
pumping residual gas out of the process chamber.

18. The method of claim 17, wherein depositing the nitride layer includes supplying argon and helium to the process chamber.

19. The method of claim 17, wherein forming the nitride film is performed at a temperature less than or equal to 350 degrees Celsius.

20. The method of claim 17, wherein the in-situ treatment includes exposing the nitride layer to a plurality of gases including nitrogen and one or more of argon and helium.

21. The method of claim 20, wherein each one of the N nitride layers includes a densified portion at a surface of the nitride layer as a result of performing the in-situ treatment.

22. The method of claim 17, wherein:
the exposed surface of the substrate includes a first oxide film formed in the process chamber; and
forming the nitride film on the substrate corresponds to forming the nitride film on the first oxide film.

23. The method of claim 22, further comprising:
forming in the process chamber a second oxide film on the nitride film, wherein the first oxide film, the nitride film, the second oxide film are collectively formed in the process chamber while maintaining a pressure of the process chamber at a subatmospheric level.

24. The method of claim 17, wherein the nitride film has a step coverage of at least 70%, in which the step coverage is defined as a first thickness of the nitride film on a first surface substantially perpendicular to a wafer chuck of the process chamber divided by a second thickness of the nitride film on a second surface substantially parallel to the wafer chuck.

25. An apparatus comprising:
a metal-insulator-metal (MIM) capacitor including:
a first metallic layer;
a first oxide film on the first metallic layer;
a nitride film on the first oxide film, the nitride film having multiple nitride layers, wherein each nitride layer includes a densified portion at a surface facing away from the first oxide film;
a second oxide film on the nitride film; and
a second metallic layer on the second oxide film.

26. The apparatus of claim 25, wherein:
the nitride film includes a base portion and a sidewall portion substantially perpendicular to the base portion;
the sidewall portion has a first thickness; and
the base portion has a second thickness greater than the first thickness.

27. The apparatus of claim 25, wherein:
the nitride film includes a base portion and a sidewall portion substantially perpendicular to the base portion; and
the nitride film has a step coverage of at least 70%, in which the step coverage is defined as a first thickness of the sidewall portion divided by a second thickness of the base portion.

28. The apparatus of claim 25, wherein the MIM capacitor has a breakdown voltage greater than 33 volts.

29. The apparatus of claim 25, wherein the MIM capacitor has a capacitance density greater than 1.6 fF/μm².
